(19) United States
(12) Patent Application Publication
(10) Pub. No.: US 2008/0020578 A1
(43) Pub. Date: Jan. 24, 2008

(54) Composition for Chemical-Mechanical Polishing (Cmp)

(76) Inventors: Gerhard Auer, Krefeld (DE); Frank Hipler, Dortmund (DE); Gerfried Zwicker, Itzehohe (DE)

Correspondence Address: WILLIAM COLLARD;COLLARD & ROE, P.C., 1077 NORTHERN BOULEVARD, ROSLYN, NY, 11576, US

(21) Appl. No.: 11/587,278

(22) PCT Filed: Apr. 12, 2005
(86) PCT No.: PCT/EP05/03850

§ 371 Date: Oct. 23, 2006

(30) Foreign Application Priority Data
Apr. 22, 2004 (DE) 10 2004 020 213.3

(51) Int. Cl. C01G 23/047; C01G 23/053; C09K 3/14; H01L 21/302

(52) U.S. Cl. 438/693; 252/79.2

(57) ABSTRACT

A material which has a high removal rate with a simultaneously gentle polishing behavior is to be made available with a composition in the form of a dispersion or a slurry for the chemical-mechanical polishing (CMP) in the production of electronic or microelectronic components, in particular, semiconductor elements, and/or a mechanical component, in particular, a microelectromechanical component or semiconductor element (MEMS).

This is attained in that the composition contains titanium oxide hydrate particles with the approximation formula TiO₂*xH₂O*yH₂SO₄, wherein the H₂O content of the titanium oxide hydrate particles is 4-25 wt %, preferably 2-10 wt %, and the H₂SO₄ content is 0-15 wt %, preferably 0.1-10 wt %.

The invention concerns compositions in the form of a dispersion or a slurry for chemical-mechanical polishing (CMP) in the production of electronic or microelectronic components, in particular, semiconductor elements, and/or a mechanical component, in particular, a microelectromechanical component or semiconductor element (MEMS).

Furthermore, the invention concerns a method for the production of an electronic or microelectronic component, in particular, a semiconductor element, and/or a mechanical component, in particular, a microelectromechanical component or semiconductor element (MEMS), which is subjected to a chemical-mechanical polishing process (CMP), under the influence of a titanium-containing composition in the form of a dispersion or a slurry. It is also directed toward a microelectronic component, in particular, a semiconductor element, and/or a mechanical component, in particular, microelectromechanical component or semiconductor element (MEMS), produced according to this method.

Finally, the invention concerns a chemical-mechanical polishing (CMP) carried out by using the preceding composition.

The dispersion or slurry is a polishing liquid which is used in so-called chemical-mechanical polishing (CMP), which is also called a chemical-mechanical planarization.

In modern integrated circuits (IC), a large number of microelectronic components such as transistors, diodes, capacitors and the like are produced on a substrate, for example, silicon or other semiconducting, insulating, or conducting materials. The circuits consist of structured, semiconducting, nonconducting, and electrically conductive thin layers. These structured layers are usually produced in that a layer material is applied by physical or chemical means (for example, evaporation, cathode sputtering, chemical deposition from the vapor phase or something similar), and is structured by a microlithographic method. By the combination of the different semiconducting, nonconducting, and conducting layer materials, the electronic circuit elements of the IC, such as transistors, capacitors, resistors and others, are defined and produced.

These individual circuit elements must be connected with one another by means of a so-called metallization, in accordance with the required functionality of the integrated circuit. To this end, a so-called intermediate level dielectric is deposited via the elements, and passage openings in the dielectric layer are formed. Subsequently, the deposition of the metal for the actual conducting paths is carried out. Two methods are usually used for the structuring of the metal. In a first method, the metal, for example, aluminum, is structured with a photolithographically applied lacquer mask by, for example, ion etching (RIE). In a second method, which is preferably used if the metal cannot be etched by means of RIE, the passage openings and trenches etched into the intermediate level dielectric are filled with metal, for example, copper or tungsten, in order to prepare the electrical connection of the individual semiconductor elements (so-called damascene or dual-damascene method). Repolishing by means of chemical-mechanical polishing (CMP) leads to the metal-filled trenches or passage openings. As a result of the constantly increasing number of semiconducting elements and the immense complexity of modern integrated circuits, a large number of metallization layers must typically be stacked on one another in order to attain the required functionality.

Within the framework of an economical manufacturing of the integrated circuits, the structural widths of the circuits are regularly reduced—that is, the circuits are smaller and the substrate surface—that is, the disk diameter (wafer diameter)—and thus the number of circuits on the wafer increases. The lithography methods used to attain the desired structural widths—with the most modern ICs, in the sub-100-nm range—have a depth-of-focus (DOF) of <1 μm—that is, extremely flat substrate surfaces are needed. Structures which are imaged in ranges above or below the depth-of-focus appear unclear and exhibit deviations from the theoretical size of the structure. Proceeding from ultra-smooth substrates (wafers) whose surfaces are produced by using CMP, the wafers have to be repeatedly planarized if the topography on the disk surface exceeds the permitted DOF. This always occurs with the first metallization scheme described, if the conducting paths, for example, made of aluminum, which have a thickness of 0.5-0.8 μm, cross or intersect. A planarization of the intermediate level dielectric by means of CMP provides a remedy. Otherwise, short circuits, interrupted connections, defective contacts between the planes or finally, reliability problems during the operation of the ICs can appear. The use of the damascene or dual-damascene technology with tungsten passage contacts or copper conducting paths—that is, the production of engraved conducting paths, automatically leads to planar surfaces during the polishing of protruding metal, and for this reason, this technology is being accepted more and more.

Chemical-mechanical polishing is used beyond the already mentioned applications also—for example, in the creation of trench isolation between the components (shallow trench isolation—STI), in the definition of the control electrodes in MOS transistors (metal gates), in the production of microelectromechanical systems (MEMS), in the manufacturing of hard disks and hard-disk writing/reading heads, and so forth. The CMP brings about both a local and also the total planarization of the structured surfaces, comprising the entire wafer surface, by the wearing down of elevated layer parts, until a plane surface is obtained. In this way, it is possible to bring about the next layer structure on a plane surface without height differences, and the desired precision of the structuring and the reliability of the components of the circuit can be attained.

A CMP step is carried out with the aid of special polishing machines, polishing cloths (pads), and polishing agents (polishing slurries). A polishing slurry is a composition which, in combination with the polishing cloth, the so-called pad, brings about a wearing down of the material to be polished on a wafer or another substrate on the polishing machine. A wafer is a polished silicon disk on which integrated circuits are arranged. CMP processes can be used on different materials, which, for example, contain oxide, nitride, semiconducting, or metal components.

In polishing processes, polishing pads and polishing liquids carry out important functions. Thus, for example, the polishing pad influences the distribution of the polishing liquid on the wafer, the transporting away of the removed material or also the formation of topological features (planarity). Important characterizing features of a polishing pad are, for example, its pore shape and size, its hardness and compressibility. The polishing liquid contains, for example, the necessary chemicals and abrasive materials, dilutes and transports removed material, and influences, for example, the removal rates of a CMP process with regard to different materials. Characterizing features of a polishing liquid are, for example, its content of chemicals and abrasive materials with regard to type and quantity, the particle size distribution, the viscosity and colloidal and chemical stability. An overview of the technology of the CMP can be found, for example, in J. M. Steigerwald, S. P. Murarka, and R. J. Gutmann, “Chemical Mechanical Planarization of Microelectronic Materials,” John Wiley & Sons Inc., New York (1996), B. L. Mueller, and J. S. Steckenrider, Chemtech (1998), pages 38-46, or in R. Waser (Editor), “Nanoelectronics and Information Technology—Advanced Electronic Materials and Novel Devices,” Verlag Wiley-VCH Weinheim (2003), pages 264-271.

Polishing liquids are typically multicomponent systems consisting of liquid components and dissolved additives (for example, organic and inorganic acids or bases, stabilizers, corrosion inhibitors, surface-active substances, oxidizing agents, buffers, complexing agents, bactericides and fungicides) and abrasive materials (for example, silicon oxide, aluminum oxide, cerium oxide), dispersed in a liquid medium, typically water. The concrete composition is determined by the material to be polished.

Particularly in polishing steps in which semiconductor layers participate, the requirements as to the precision of the polishing step and thus as to the polishing slurry are particularly great. A number of variables with which the effect of the polishing slurry is characterized serve as an evaluation scale for the effectiveness of polishing slurries. Among these variables are the removal rate—that is, the rate at which the material to be polished is removed, the selectivity—that is, the ratio of the removal rates of materials to be polished to other materials present, and variables for the uniformity of the planarization. These describe an attained degree of planarization (flatness), an undesired polishing into the material (dishing), or an undesired removal of other adjacent materials (erosion). Among the variables describing the uniformity of the planarization, however, are also the uniformity of the remaining layer thickness within a wafer (within-wafer nonuniformity, WIWNU) and the uniformity of wafer-to-wafer (wafer-to-wafer nonuniformity, WTWNU), and the number of defects per unit surface (for example, scratches, surface roughness, or adhesive particles).

For the production of the IC, the so-called copper-damascene process is being increasingly used (see, for example, “Microchip Fabrication: A Practical Guide to Semiconductor Processing,” Peter Van Zant, 4th ed., McGraw-Hill, 2000, pp. 401-403 and 302-309; “Copper CMP: A Question of Tradeoffs,” Peter Singer, Semiconductor International, Verlag Cahners, May 2000, pp. 73-84; U. Hilleringmann, “Silicon Semiconductor Technology,” Teubner Verlag, 3rd Edition, 2003). It is in that case necessary to remove a Cu layer chemomechanically with a polishing slurry (so-called Cu-CMP process), in order to produce Cu conductor paths. The finished Cu conductor paths are embedded in a dielectric. Between copper (Cu) and the dielectric, there is a barrier layer, in order to prevent a diffusion of copper, in the long run, into the silicon (Si)-substrate material, which would result in negative consequences for the efficiency of the IC. Peculiarities and difficulties result from this structure with regard to the required polishing techniques. In one typical IC production process, copper is deposited on a barrier layer made of tantalum/tantalum nitride. Other metals, their nitrides or silicides can also be used for the above purpose. In the planarization to be carried out, it is necessary to remove the excess copper and barrier material without attacking the layer of the dielectric underneath. Influenced by various material characteristics of the copper (relatively soft, slightly oxidizable) and the tantalum (relatively hard), special demands are made of a polishing process. The state of the art for the Cu-CMP process is a multistage process. The Cu layer is first polished with a polishing slurry, which guarantees a high Cu removal. Subsequently, a second polishing slurry is used, in order to remove the protruding barrier layer. After the subsequent cleaning steps, a planar surface with the shiny polished dielectric and the embedded conducting paths is obtained. For the first polishing step, one uses, for example, a polishing slurry with a high selectivity—that is, in that the removal rate for Cu is as high as possible and for the material of the barrier layer underneath is as small as possible. The polishing process is stopped automatically as soon as the barrier layer under the Cu is exposed. For the removal of the barrier layer in a second polishing step, polishing slurries with a high removal rate for the barrier layer are used. The removal rate for Cu is lower than or the same as the removal rate for the barrier layer. To avoid dishing and erosion, the removal rate of the dielectric should be on the same order of magnitude.

CMP slurries for the polishing of metal, for example, for the first copper polishing step, contain one or more chemical compounds which react, for example, oxidize, with the material of the layer to be leveled, wherein afterwards the reaction product, for example, the metal oxide, is removed mechanically with abrasive substances in the slurry or on the polishing pad. Exposed metal is then etched slightly with other chemical compounds, before, once more, a protective oxide coating is formed and the cycle can begin anew. Removal and the attained planarity depend on the pressure between the workpiece and polishing pad, on the reactive rate between the two and with chemically dominated processes, on the temperature.

From the state of the art, the use of, for example, silicon oxide, aluminum oxide, cerium oxide, or titanium oxide, as the abrasives in polishing slurries for the first polishing step is known (see, for example, WO-A 99/64527, WO-A 99/67056, U.S. Pat. No. 5,575,837, and WO-A 00/00567). The disadvantage of polishing slurries based on aluminum oxide is the high degree of hardness of the abrasive, which, increasingly, leads to scratches on the wafer surface. This effect can be reduced in that the aluminum oxide is produced via gas-phase processes and not via melting processes. In this process, one obtains irregularly shaped particles which are sintered together from many small primary particles (aggregates). The gas phase process can also be used for the production of titanium dioxide or silicon dioxide particles. Angular particles scratch, in principle, more than round, spherical particles. Particularly, smoothly polished surfaces with roughnesses in the range clearly below 1 nm, for example, on the dielectric material silicon dioxide are attained with round, spherical, colloidal silicon dioxide particles (precipitated silicic acid).

A dispersion with abrasive particles and a photocatalytic effect caused by TiO₂ during irradiation with light, for example, ultraviolet light, is known from US 2003/0022502 A1. The photocatalytic effect hereby supports the oxidation of the metal layer to be eliminated and thus improves the abrasive effect of the dispersion.

A dispersion composition with photocatalytic effect and a mixture of TiO₂ and Ti₂O₃ as a catalyst is known from U.S. Pat. No. 6,177,026 B1.

The disadvantage of this state of the art is that when using titanium dioxide corresponding to the state of the art, the size or the size distribution of the abrasive particles is not optimal—in particular, there is an excessive number of coarse particles—and therefore either only low removal rates are attained or coarse particles or agglomerates of the abrasive particles cause scratches, grooves, or irregular removal rates and impair the uniformity and efficiency of the CMP process. Slurries with low friction to avoid shear forces are needed, which should prevent any layer delaminations during the polishing, in particular for the polishing of novel materials with a low dielectric constant (low-k materials), which consist of doped oxides or nanoporous polymer materials. Another disadvantage of the state of the art is the tedious and expensive production process of the dispersion particles, which to a particular extent, applies to the production of nanoparticles from gas-phase processes.

In particular, with the intended utilization of the photocatalytic effect, the variants of titanium dioxide, known according to the state of the art, do not offer optimal characteristics, for example, sufficient photocatalytic activity.

In contrast to this, the goal of the invention is to prepare a composition or a material for such a composition, which has a high removal rate with a simultaneous gentle polishing behavior.

With a composition of the type mentioned in the beginning, the goal is attained in accordance with the invention in that the composition contains titanium oxide hydrate particles with the approximation formula TiO₂*xH₂O*yH₂SO₄, wherein the H₂O content of the titanium oxide hydrate particles is 0.4-25 wt %, preferably 2-10 wt %, and the H₂SO₄ content is 0-15 wt %, preferably 0.1-10 wt %.

Here, the indicated and all subsequently listed weight percent values refer to a sample dried according to ISO 787, Part 2.

Titanium oxide hydrate or titanium oxide hydrate particles are hereby understood to mean a titanium oxide-containing material with chemisorbed water and perhaps H₂SO₄ and/or other inorganic and/or organic components, which can be represented also, in part, with the approximation formula TiO(OH)₂.

With regard to its suitability for the CMP process, the titanium oxide hydrate shows clear advantages in comparison to traditional titanium dioxide with only low quantities of chemisorbed water (such as commercial titanium dioxide pigments).

The determination of the H₂O content of the titanium oxide hydrate particles can take place according to the following equation:
H₂O content (%)=Ignition loss (%)−H₂SO₄ content (%)
wherein the ignition loss is the weight loss of a sample dried according to ISO 787, Part 2, after one hour of igniting at 1000° C., and the H₂SO₄ content is determined by the analytical determination of the sulfur in the sample dried according to ISO 787, Part 2, and conversion to H₂SO₄.

Approximately, the determination of the H₂O content of the titanium oxide hydrate particles can also be equated with the ignition loss (in %) after one hour of igniting of the sample dried according to ISO 787, Part 2, at 500° C.

An exact determination of the H₂O content of the titanium oxide hydrate particles can, however, take place basically after one hour of igniting of the sample dried according to ISO 787, Part 2 at 1000° C. and a gas chromatographic analysis of the volatile components.

A particularly gentle mechanical stress of the surface to be processed with a simultaneously sufficiently high abrasivity is produced by the invention as a result of the high specific surface of titanium oxide hydrate and the small particle size of titanium oxide hydrate with chemical-mechanical polishing. This can be supported also by the utilization of the photocatalytic effect of titanium oxide hydrate.

A performance and operating behavior of the abrasive particles, with regard to the total evaluation of removal rate, planarity, selectivity, and defect density, which is better in comparison to the previous state of the art, is revealed. A favorable combination of a high removal rate-produced by the catalytic or photocatalytic characteristics of the titanium oxide hydrate—and gentle abrasion behavior is attained with the production process connected with this invention when using the composition or with the titanium oxide hydrate particles which are the basis of this invention.

By means of a purposeful design of the characteristic particle characteristics, it is possible to combine a photocatalytic effect with improved abrasive characteristics, so that it is not absolutely necessary to add other abrasive materials, aside from those which are the basis of this invention. This reduces the quantity of expendable materials and has an economizing effect on resources.

Especially with the intended use of the photocatalytic effect, the titanium oxide hydrate particles offer an optimal combination of characteristics. In addition to a very large BET surface, titanium oxide hydrate particles offer a high catalytic activity, which can be optimized with respect to the individual application purpose, by a specific, easily implemented modification for example, with metals or metal compounds.

The composition in accordance with the invention is characterized by a high abrasivity with a very gentle treatment of the polished surfaces at the same time.

Furthermore, the composition in accordance with the invention is characterized by a high catalytic or photocatalytic activity. This is related, on the one hand, to the specific physical characteristics of the titanium oxide hydrate particles, but on the other hand, also on the high specific surface of the titanium oxide hydrate and on its acidity. Moreover, it is possible to influence or to increase the catalytic activity with chemical additives, for example, with additives of metal ions such as Fe, Co, Ni, V, Mo, Ag, Pd, Ru, Rh. These chemical additives can be admixed with the titanium oxide hydrate or can be applied to the titanium oxide hydrate, but they can also be incorporated into the titanium oxide hydrate by a calcination or tempering process.

In accordance with the development of the invention, it is possible for the titanium oxide hydrate particles to contain up to 10 wt % other inorganic and/or organic compounds, preferably up to 3 wt %.

The titanium oxide hydrate particles can be obtained by the hydrolysis of inorganic or organic titanium compounds. Depending on the titanium compound and the reaction conditions, different characteristics of the titanium oxide hydrates are produced thereby.

Preferably, to obtain the titanium oxide hydrate, the production method for titanium dioxide according to the sulfate process can be used, which, for example, is described in detail in Industrial Inorganic Pigments (2nd Edition, Gunter Buxbaum, Editor, Wiley-VCH, 1998).

Therefore, the invention, in its development, provides for the titanium oxide hydrate to be particles yielded after the hydrolysis in the production of titanium oxide according to the sulfate method.

Particularly preferred, is that the titanium oxide hydrate obtained after the hydrolysis is freed from adhering impurities, in that it is either filtered and washed or is also additionally subjected to the method step of so-called bleaching, a chemical treatment with reducing agents to eliminate trivalent iron.

The large-scale production of titanium oxide hydrate according to the sulfate process for the production of titanium dioxide has the advantage of a constant product quality and constant availability.

Preferably, the composition contains titanium oxide hydrate in a fraction of 0.1-30 wt %, preferably 3-20 wt %. The concentration optimal for the individual application purpose can be easily determined by the specialist by means of simple experiments.

It may be advantageous to treat the titanium oxide hydrate by a calcining or tempering step, in order to increase the particle size and the abrasivity or to purposefully modify the catalytic or photocatalytic characteristics. In particular, the conversion of amorphous titanium oxide hydrate into microcrystalline anatase can be advantageous. The calcining or tempering step should, however, go only so far that the special characteristics of the titanium oxide hydrate are not lost—that is, the fraction of chemisorbed water (for example, in the form of hydroxyl groups) may not be smaller than 0.4 wt %, preferably 2.0 wt %, in order to retain a catalytically or photocatalytically reactive surface of the titanium oxide hydrate.

With the titanium oxide hydrate calcined at high temperatures, the catalytic or photocatalytic activity, on the other hand, clearly recedes, whereas the titanium oxide hydrate is converted to “macrocrystalline” (with a crystal size of >100 nm) TiO₂ (in the anatase or rutile modification) with a content of chemisorbed water of clearly smaller than 1 wt %. In accordance with the development of the invention, it is advantageous if the titanium oxide hydrate particles have an ignition loss of >2 wt %, preferably >6 wt %, at 1000° C. This is with an igniting of 1 h at 1000° C. The determination of the ignition loss takes place thereby on a sample from the titanium oxide hydrate particles, predried according to ISO 787, Part 2.

In accordance with the development of the invention, it is also advantageous if the titanium oxide hydrate particles have an ignition loss of >0.8 wt %, preferably >1.2 wt %, with an ignition of 1 h at 500° C. The determination of the ignition loss thereby takes place also on a sample from titanium oxide hydrate particles, predried according to ISO 787, Part 2.

Preferably, the BET surface of the titanium oxide hydrate is 150-400 m²/g, with particular preference 250-380 m²/g, which the invention also provides. The determination of the BET surface takes place thereby, according to DIN 66131, on a sample from the titanium oxide hydrate particles, degassed and dried at 140° C. for 1 h.

The invention is also characterized in that the average particle size of the primary particles of the titanium oxide hydrate is 3-15 nm, preferably 4-8 nm. This is attained, for example, by the preceding method steps, through which, in contrast to traditional gas-phase processes, a technically and economically improved production process is made available for the formation of nanoparticular titanium oxide hydrate-containing abrasive materials.

The primary particles are small, approximately spherical, microcrystalline particles with a lattice-defective anatase structure. The particle size can be determined either by electron microscope or calculated from the BET surface.

These primary particles form flake-like structures of approximately 30-60 nm in diameter which are designated as secondary particles. These secondary particles are very stable, with respect to mechanical and chemical influences. They can be partially destroyed mechanically, only with a very high energy use; even chemically, a splitting of the secondary structure into isolated primary particles is very difficult (see U.S. Pat. No. 5,840,111).

The secondary particles form, in turn, tertiary particles (ca. 1000 nm), which are irregularly (cloud-like) shaped and deform by the use of mechanical energy, and in contrast to the primary and secondary particles, can be partially divided up also with a high mechanical energy input. With a particle size determination of the titanium oxide hydrate by means of laser diffraction, only the tertiary particles are very predominantly detected and measured even with a strong ultrasonic dispersion.

Both the secondary and the tertiary particles are firmly held together by van der Waals' forces and electrostatic forces, but are not rigid structures. Their mode of action with regard to the mechanical stress, as it occurs in the CMP process, can be compared with a flexible polishing pad, which is covered with extremely finely divided, abrasive particles: on the one hand, microcrystalline primary particles, which develop a mechanical abrasion effect, are present; on the other hand, these primary particles are bound into a stable but nevertheless flexible structure, which makes possible both an efficient force transfer from the polishing pad to the surface to be polished and an adaptation of the abrasion effect to the surface texture. The result from this is that exposed areas on the surface to be polished are mechanically abraded more intensely and deeper areas more weakly. This structure of the titanium oxide hydrate particles is particularly advantageous, because as a result of the very small primary particles of the CMP process, on the one hand, a very smooth surface of the microelectronic components is produced; on the other hand, however, an efficient force transfer from the rotating polishing disk to the surface to be polished takes place due to the binding of the primary particles into the secondary particles or tertiary particles. In this way, both very smooth surfaces and also good removal rates can be obtained. Thus, the CMP process is influenced in the desired manner by the specific structure of the titanium oxide hydrate particles.

The titanium oxide hydrate particles for use in a composition according to one of claims 1-22 can be produced in good quality, at low cost, by the hydrolysis of titanyl sulfate solution and the subsequent separation and perhaps cleaning of the titanium oxide hydrate obtained.

In a further development, the invention therefore provides for the titanium oxide hydrate to be produced by the hydrolysis of titanyl sulfate solution, the subsequent separation, and perhaps the cleaning of the titanyl oxide hydrate thereby obtained.

With titanium oxide hydrate as it is obtained in the hydrolysis of titanyl sulfate solution, a particularly advantageous combination of characteristics is present:

On the one hand, this titanium oxide hydrate has very small primary particles of microcrystalline anatase, wherein a high photocatalytic activity and at the same time, a gentle surface treatment are brought about. On the other hand, an efficient transfer from the polishing pad to the wafer surface can take place because of the secondary particles, wherein, in addition, a mechanical component contributes to an optimal removal behavior.

The titanium oxide hydrate particles can, for example, be obtained by the hydrolysis of a sulfuric acid-containing titanyl sulfate solution. Depending on the origin and composition of the sulfuric acid-containing titanyl sulfate solution, a sulfuric-acid suspension of titanium oxide hydrate during the hydrolysis is obtained which can still contain undesired impurities—in particular, heavy metals. As a rule, therefore, one or more cleaning steps are undertaken, in order to free the titanium oxide hydrate from undesired impurities.

For the highest purity, it is advantageous not to use the large-scale metal ion-containing, sulfuric acid-containing titanyl sulfate solution, but rather a synthetic sulfuric acid-containing titanyl sulfate solution, which contains only small quantities of impurities. The production of a highly pure titanium oxide hydrate therefrom can take place either analogous to traditional, large-scale processes or with some differences.

The small content of metal trace elements can have a favorable effect on the defect density or reliability of the integrated circuits.

It is thereby advantageous also if the titanium oxide hydrate is deflocculated by the addition of HCl (hydrochloric acid) at least in part, which the invention also provides for. This deflocculation—that is, the partial decomposition of the secondary and/or tertiary particles—can be attained in a solution strongly acidified by hydrochloric acid by electrical charge reversal of the particle surface. In this way, a de facto more finely divided particle structure is attained which can manifest itself particularly positive on the homogeneity of the removal or on the attainable surface roughness.

It is also advantageous if the titanium oxide hydrate is present as a transparent sol. This transparent sol from isolated titanium oxide hydrate primary particles has a minimal mechanical removal effect (comparable with a CMP solution without any solids fraction), and can be used, however, for specific CMP processes as a result of the photocatalytic characteristics of the titanium oxide hydrate.

Such a sol can be produced as described in U.S. Pat. No. 5,840,111.

Furthermore, it is advantageous for the photocatalytic characteristics if the titanium oxide hydrate contains 20-2000 ppm niobium (Nb), relative to TiO₂, preferably, 50-500 ppm niobium (Nb), which the invention provides for in a further development.

It is particularly advantageous for the photocatalytic characteristics if in the titanium oxide hydrate, the molar ratio of niobium to aluminum Nb/Al is >1, preferably >10, and/or the molar ratio of niobium to zinc (Nb/Zn) is >1, preferably >10. Such a photocatalytic material or a composition, in accordance with the invention, with this material is characterized by a particularly good photocatalytic effect.

It is also advantageous if the rutile content of the titanium oxide hydrate is less than 10 wt %, preferably less than 1 wt %, since the photocatalytic characteristics of anatase is, as a rule, more pronounced than that of rutile.

It is also advantageous if the titanium oxide hydrate contains 20-2000 ppm chloride, preferably, 80-800 ppm. This influences the photocatalytic characteristics positively.

It is also advantageous if the titanium oxide hydrate contains less than 1000 ppm carbon, preferably, less than 50 ppm, which the invention also provides for. This also influences the photocatalytic characteristics positively.

An appropriate refinement of the invention is to be found in that the titanium oxide hydrate contains less than 100 ppm iron, aluminum, or sodium, preferably, less than 15 ppm. In microelectronic applications, a low content of metal ions, such as iron, in polishing liquids favorably influences the reliability of the chemomechanically polished components, under the influence of the composition, in accordance with the invention. The introduction of contaminations into the substrates, which negatively influence the charge carrier service life is minimized or hindered.

It is also advantageous if the titanium oxide hydrate is coated with an inorganic and/or with an organic compound.

Thus, in addition to the abrasive and photocatalytic characteristics of the titanium oxide hydrate, the zeta potential, surface morphology, tribological characteristics, and other physicochemical characteristics of the abrasive particles are purposefully adjusted, depending on the requirement of the substrate to be polished, and thus, for example, positively influence the selectivity, removal performance, or characteristics with regard to the post-CMP cleaning.

It is also advantageous hereby if the titanium oxide hydrate is coated with noble metals or noble metal compounds. In this way, the photocatalytic characteristics can also be improved or purposefully, positively influenced.

Usually, the CMP process—with the composition of the invention also—is carried out at pH values of 9-11 for oxide-CMP (for example, SiO₂) or with pH values of 3-7 with metal-CMP (for example, copper).

In accordance with another development, the invention, conversely, provides for the composition to have a pH value smaller than 2, preferably, smaller than 1, or a pH value greater than 12, preferably, greater than 13.

An advantageous variant of the invention is found in that the composition, in accordance with the invention, with titanium oxide hydrate as the abrasive has a pH value greater than 12, preferably, greater than 13. In contrast to the compositions used according to the state of the art which contain SiO₂ or Al₂O₃ as the abrasive, the titanium oxide hydrate in the composition in accordance with the invention also does not exhibit any solubility with extremely high pH values. In this way, the removal rate can be considerably increased, in particular, with the CMP process on oxide surfaces (for example, SiO₂).

However, even with low pH values smaller than 2, preferably smaller than 1, the titanium oxide hydrate exhibits a very high stability. In particular, in a solution acidified with hydrochloric acid, the titanium oxide hydrate (in contrast to SiO₂ or Al₂O₃) in the composition of the invention does not exhibit an appreciable solubility with extremely low pH values either. In this way, the removal rate can be considerably increased, especially with the CMP process on metal surfaces (for example, Cu, W, or Ta).

In an advantageous manner, the invention also provides for the composition to contain one or more other abrasives and/or solids also. In this way, for example, the selectivity of a polishing liquid can be purposely adjusted with respect to the substrate surface.

In addition to the preceding, it is, of course, also possible to add, in addition to titanium oxide hydrate, other solid particles also, with conditions which are particularly suitable for the effectiveness of the photocatalytic effect, in order to attain the highest possible mechanical removal rates. A mixture of various components of which the titanium oxide hydrate acts predominantly (but not only) photocatalytically, whereas other components act chemically or mechanically, can be particularly advantageous.

It can also be advantageous if the composition contains titanium dioxide (TIO₂). In this way, the photocatalytic characteristics of the titanium oxide hydrate can be combined well with the abrasive characteristics of TiO2, and positive synergy effects can be attained and utilized.

In a method of the initially designated type, the aforementioned goal is attained in that during the chemical-mechanical polishing, a composition according to one of claims 1-22 is applied on the surface of the component and while polishing, is moved over the surface.

Hereby, the photocatalytic effect of the titanium oxide hydrate or the composition can be used in a supporting manner, so that the invention is characterized in that during the chemical-mechanical polishing, a composition according to one of claims 1-22 is subjected to an irradiation with visible and/or ultraviolet light for the initiation and utilization of a photocatalytic effect.

Furthermore, the aforementioned goal is attained by a microelectronic component, in particular, a semiconductor element, and/or a mechanical component, in particular, microelectromechanical component or semiconductor element (MEMS), produced according to the preceding method.

Also, the aforementioned goal is attained by a chemical-mechanical polishing (CMP), which is carried out using a composition according to one of the aforementioned feature combinations, which the invention also provides for. Hereby, it is particularly advantageous if a metal, an electrically conductive and/or a dielectric structure is chemomechanically polished, which the invention provides for in its development.

Finally, it is particularly advantageous to carry out a chemical-mechanical polishing using the composition in accordance with the invention if a copper-containing structure is polished chemomechanically, which the invention, finally, also provides for.

The invention is explained in more detail below with the aid of some selected examples, wherein the invention is in no way limited to the specific examples.

### EXAMPLE 1

### CMP Removal Characteristic with Silicon Dioxide Layers

The removal behavior of the compositions in CMP processes, which are the basis for this invention, was described by diverse polishing tests, which were all carried out on a Peter Wolters PM200 Gemini CMP cluster tool from the Peter Wolters Surface Technologies GmbH, equipped with a polishing machine, brush cleaner, and automatic wafer handling. As substrates, 150 mm (diameter) silicon wafers with a coating of 1000 nm SiO₂ (thermally oxidized) were used.

As a polishing pad, a Suba 500 from Rohm & Haas Electronic Materials was used.

For all polishing processes, the machine parameters summarized in Table 1 were used.

TABLE 1
Machine parameters of the polishing processes

| | | |
|---|---|---|
| Force | 900 | N |
| Backside pressure wafer-chuck | 15 | kPas |
| Chuck speed | 44 | rpm |
| Polishing disk speed | 45 | rpm |
| Dispersion flow | 180 | mL/min |

For each dispersion, 3 wafers were polished every 120 s. After each wafer, the polishing pad was conditioned with a nylon brush. Control wafers were treated between the individual test dispersions in order to rule out or to minimize a falsification of the measurement values by entrainment. The two-fold cleaning of the wafer after the polishing step was carried out with the aid of PVA brushes and deionized water. The removal performances attained with the dispersions and the nonuniformity were determined after the polishing and cleaning had been done by reflectometric measurements of the oxide layer thickness with a Sentech spectral photometer.

The titanium dioxide hydrate-containing materials, which are the basis of the invention were tested (unless otherwise specified) in the form of aqueous dispersions with a solids content of 25 wt % in the pH range of 9-10 as polishing liquids. The composition of the polishing liquids and the polishing results are summarized in Table 2.

TABLE 2
Composition and polishing results of the tested dispersions for SiO₂-CMP.

| | | | | Removal | |
|---|---|---|---|---|---|
| | Average particle | | Solids content | Rate | Non-Uniformity |
| Dispersion | diameter[nm] | pH | [%] | [nm/min] | [%] |
| 1-A | 6 | 11.8 | 25 | 16 | 21 |
| 1-G | 6 | 1.19 | 25 | 9 | 8.5 |
| 1-H | 6 | 9.92 | 25 | 84 | 9.4 |
| 1-J (Comparative | 25 | 10.19 | 12.5 | 228 | 5.2 |
| example) | | | | | |

Dispersion 1-A in accordance with the invention, with titanium oxide hydrate, in the form of relatively soft aggregates as secondary particles, shows a low removal performance in comparison to a typical oxide-CMP process. It may, however, be advantageous to use this dispersion in accordance with the invention for metal-CMP processes or photocatalytically reinforced metal-CMP processes. Damage to the polished surface by particle contamination and formation of scratches is not observed.

Dispersion 1-G in accordance with the invention shows the lowest removal rate because of the low pH value. Here, the chemical component of the CMP process is still only minor, and the observed removal performance can be attributed to a purely mechanical fraction. Damage to the polished surface by particle contamination and formation of scratches is not observed. Dispersion 1-G contains the titanium oxide hydrate in deflocculated form. Therefore, the use of 1-G as a deflocculated titanium oxide hydrate for the metal-CMP area appears advantageous.

Dispersion 1-H in accordance with the invention consists of titanium oxide hydrate coated with silicon dioxide and exhibits a higher removal rate in comparison to dispersion 1-A, with a simultaneous halving of the nonuniformity. Thus, the removal performance can be advantageously influenced by the selection of suitable coatings of the titanium oxide hydrate particles. Damage to the polished surface by particle contamination and formation of scratches is not observed.

Comparison dispersion 1-J contains commercially available pyrogenic TiO₂ (Degussa P 25) and exhibits a high removal performance, but causes damage to the polished surface by particle contamination and formation of scratches. Therefore, the titanium oxide hydrate-containing, investigated dispersions exhibit advantages, during polishing, with regard to the variably adjustable removal rate and in particular, the defect density (for example, scratches, surface roughness, or adhering particles), in comparison to the investigated dispersion on the basis of pyrogenic titanium dioxide (Degussa P25), which corresponds to the state of the art.

It is obvious that the titanium oxide hydrate-containing dispersions, described here by way of example, behave advantageously with regard to the post-CMP cleaning and the deficit density on the polished surface. The presented experimental results can be transferred purposefully to different surfaces to be polished in an industrial manufacturing step by the combination with additives and auxiliaries or adaptation of the production conditions of the titanium oxide hydrate-containing materials (depending on the desired ratio of chemical, mechanical or (photo)catalytic activity) and by a refined CMP process operation with regard to its removal behavior.

Particularly advantageous is the use of titanium oxide hydrate-containing dispersions, which are the basis of this invention, for the chemical-mechanical planarization of metal substrates, such as copper.

Furthermore, the use of the polishing liquids as described in this invention with titanium oxide hydrate is advantageous for the use of photocatalytically aided CMP methods.

1. Composition in the form of a dispersion or a slurry for chemical-mechanical polishing (CMP) in the production of electronic or microelectronic components, in particular, semiconductor elements, and/or a mechanical component, in particular, a microelectromechanical component or semiconductor element (MEMS), wherein the composition contains titanium oxide hydrate particles with the approximation formula TiO₂*xH₂O*yH₂SO₄, wherein the H₂O content of the titanium oxide hydrate particles is 0.4-25 wt %, preferably 2-10 wt %, and the H₂SO₄ content, 0-15 wt %, preferably 0.1-10 wt %.

2. Composition according to claim 1, wherein the titanium oxide hydrate particles contain up to 10 wt % of other inorganic and/or organic components, preferably up to 3 wt %.

3. Composition according to claim 1, wherein the titanium oxide hydrate particles are particles yielded after the hydrolysis in the production of titanium dioxide according the sulfate method.

4. Composition according to claim 1, wherein it contains titanium oxide hydrate in a fraction of 0.1-30 wt %, preferably 3-20 wt %.

5. Composition according to claim 1, wherein the titanium oxide hydrate particles have an ignition loss of >2 wt %, preferably >6 wt % at 1000° C.

6. Composition according to claim 1, wherein the titanium oxide hydrate particles have an ignition loss of >0.8 wt %, preferably >1.2 wt % at 500° C.

7. Composition according to claim 1, wherein the BET surface of the titanium oxide hydrate is 150-400 m²/g, preferably 250-380 m²/g.

8. Composition according to claim 1, wherein the average particle size of the primary particles of the titanium oxide hydrate is 3-15 nm, preferably 4-8 nm.

9. Composition according to claim 1, wherein the titanium oxide hydrate is produced by the hydrolysis of titanyl sulfate solution, the subsequent separation, and perhaps the cleaning of the titanium oxide hydrate thereby obtained.

10. Composition according to claim 1, wherein the titanium oxide hydrate is deflocculated, at least partially, by the addition of HCl.

11. Composition according to claim 1, wherein the titanium oxide hydrate is present as a transparent sol.

12. Composition according to claim 1, wherein the titanium oxide hydrate contains 20-2000 ppm niobium (Nb), relative to TiO₂, preferably 50-500 ppm niobium (Nb).

13. Composition according to claim 1, wherein in the titanium oxide hydrate, the molar ratio of niobium to aluminum Nb/Al is >1, preferably >10, and/or the molar ratio of niobium to zinc (Nb/Zn), >1, preferably >10.

14. Composition according to claim 1, wherein the rutile content of the titanium oxide hydrate is less than 10 wt %, preferably less than 1 wt %.

15. Composition according to claim 1, wherein the titanium oxide hydrate contains 20-2000 ppm chloride, preferably 80-800 ppm.

16. Composition according to claim 1, wherein the titanium oxide hydrate contains less than 1000 ppm carbon, preferably less than 50 ppm.

17. Composition according to claim 1, wherein the titanium oxide hydrate contains less than 100 ppm iron, aluminum, or sodium, preferably less than 15 ppm.

18. Composition according to claim 1, wherein the titanium oxide hydrate is coated with an inorganic and/or with an organic compound.

19. Composition according to of the preceding claims claim 1, wherein the titanium oxide hydrate is coated with noble metals or noble metal compounds.

20. Composition according to one claim 1, wherein it has a pH value of smaller than 2, preferably smaller than 1, or a pH value of greater than 12, preferably greater than 13.

21. Composition according to claim 1, wherein it also contains one or more other abrasives and/or solids.

22. Composition according to claim 1, wherein it contains titanium dioxide (TiO₂).

23. Method for the production of an electronic or microelectronic component, in particular, a semiconductor element, and/or a mechanical component, in particular, a microelectromechanical component or semiconductor element (MEMS), which is subjected to a chemical-mechanical polishing method (CMP), under the influence of a titanium-containing composition in the form of a dispersion or a slurry, wherein a composition according to claim 1 is applied on the surface of the component and while polishing, is moved over the surface.

24. Method according to claim 23, wherein during the chemical-mechanical polishing, a composition according to claim 1 is subjected to an irradiation with visible and/or ultraviolet light for the initiation and utilization of a photocatalytic effect.

25. Microelectronic component, in particular, a semiconductor element, and/or mechanical component, in particular, a microelectromechanical component or semiconductor element (MEMS), produced according to a method according to claim 23.

26. Chemical-mechanical polishing (CMP), carried out with the use of a composition according to claim 1.

27. Chemical-mechanical polishing according to claim 26, wherein a metal, an electrically conductive and/or dielectric structure, is chemomechanically polished.

28. Chemical-mechanical polishing according to claim 27, wherein a copper-containing structure is polished chemomechanically.
